(19) United States
(12) Patent Application Publication
(10) Pub. No.: US 2026/0068189 A1
(43) Pub. Date: Mar. 5, 2026

(54) SEMICONDUCTOR DEVICE

(71) Applicant: MEDIATEK INC., Hsinchu City (TW)

(72) Inventors: Tzung-Lin LI, Hsinchu City (TW); Yuan-Fu CHUNG, Hsinchu City (TW); Tung-Hsing LEE, Hsinchu City (TW)

(21) Appl. No.: 19/226,450

(22) Filed: Jun. 3, 2025

Related U.S. Application Data
(60) Provisional application No. 63/687,846, filed on Aug. 28, 2024.

(51) Int. Cl. H10D 1/20; H01L 23/64; H03K 17/687

(52) U.S. Cl. CPC H10D 1/20; H03K 17/687

(57) ABSTRACT

A semiconductor device is provided. The semiconductor device includes a first port, a second port, a first inductor, a second inductor and a switch circuit. The first inductor is coupled between a first port and a second port. The first inductor includes a first strip part close to the first port. The second inductor and the switch circuit are connected in series. The series connected second inductor and the switch circuit are coupled between the first port and the second port and overlap the first inductor. The second inductor includes at least one first vertical portion that overlaps and is perpendicular to the first strip part.

### CROSS REFERENCE TO RELATED APPLICATIONS

This application claims the benefit of U.S. Provisional Application No. 63/687,846, filed on Aug. 28, 2024, the entirety of which is incorporated by reference herein.

### BACKGROUND OF THE DISCLOSURE

### Field of the Disclosure

The present disclosure relates to a semiconductor device and, in particular, it relates to a tunable inductor component.

### Description of the Related Art

LC tanks, which consist of an inductor and a capacitor, are widely used in RF/mm-wave circuits, such as frequency synthesizers/oscillators, filters, and impedance matching networks. In radio frequency (RF) and high speed Serdes (Serializer/Deserializer) applications, one criterion of inductors is low resistance, so that a high quality factor (Q factor) can be achieved. The Q factor of an inductor is the ratio of its inductive reactance to its resistance at a given frequency, and is a measure of its efficiency. The higher the Q factor of the inductor, the closer it approaches the behavior of an ideal, lossless inductor.

Thus, a novel semiconductor device having an inductor with an increased Q factor is desirable.

### BRIEF SUMMARY OF THE DISCLOSURE

An embodiment of the present disclosure provides a semiconductor device. The semiconductor device includes a first port, a second port, a first inductor, a second inductor and a switch circuit. The first inductor is coupled between a first port and a second port. The first inductor includes a first strip part close to the first port. The second inductor and the switch circuit are connected in series. The series connected second inductor and the switch circuit are coupled between the first port and the second port and overlap the first inductor. The second inductor includes at least one first vertical portion that overlaps and is perpendicular to the first strip part.

An embodiment of the present disclosure provides a semiconductor device. The semiconductor device includes a first port, a second port, a first inductor, a second inductor and a switch circuit. The first inductor is coupled between the first port and the second port. The first inductor includes an inner turn and an outer turn. The inner turn includes a first strip part close to the first port. The outer turn includes a second strip part close to and parallel to the first strip part. The second inductor and a switch circuit are connected in series. The series connected second inductor and the switch circuit are coupled between the first port and the second port and overlap the first inductor. The second inductor includes at least one first vertical portion that overlaps and is perpendicular to the first strip part and the second strip part.

### BRIEF DESCRIPTION OF THE DRAWINGS

The present disclosure can be more fully understood by reading the subsequent detailed description and examples with references made to the accompanying drawings, wherein:

FIG. 1 is a schematic plan view of a semiconductor device in accordance with some embodiments of the disclosure, showing the connection of the semiconductor device when a switch circuit is in off-state;

FIG. 2 is a schematic plan view of a semiconductor device in accordance with some embodiments of the disclosure, showing the connection of the semiconductor device when a switch circuit is in on-state;

FIG. 3 is a schematic plan view of a semiconductor device in accordance with some embodiments of the disclosure, showing the connection of the semiconductor device when a switch circuit is in off-state; and

FIG. 4 is a schematic plan view of a semiconductor device in accordance with some embodiments of the disclosure, showing the connection of the semiconductor device when a switch circuit is turned on.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

In advanced communication applications (such as Wi-Fi 7, 5G, etc.), tunable inductors play an important role due to the advantages of helping possess larger tuning range of LC-oscillators, possibility of sharing synthesizer with different bands, helping reducing chip size/form factor by using less frequency synthesizers, and facilitating broadband impedance matching. However, there may be problems with of the tunable inductor cause a problem with low quality factor (Q factor). For example, when the tunable inductor is operated to have larger inductance by the secondary inductor disconnecting the main inductor, the secondary inductor will impact Q factor of the main inductor and results in higher power consumption. When the tunable inductor is operated to have smaller inductance by parallel connecting the main inductor and the secondary inductor, the tuning range of the tunable inductor will be smaller than expected due to mutual inductance between the main inductor and the secondary inductor. These problems result in a degradation in the performance of the inductor. Thus, a novel tunable inductor with an increased Q factor and lower mutual inductance in different inductance ranges is desirable.

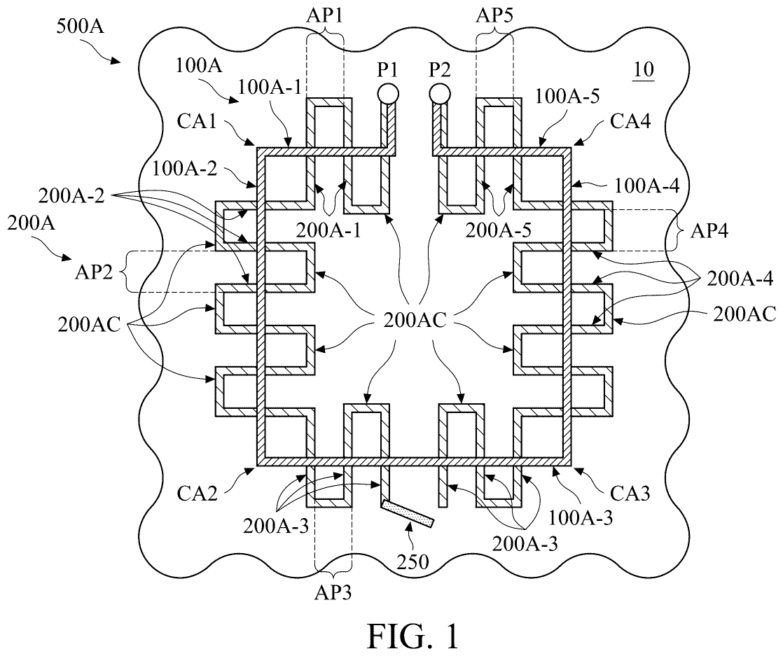

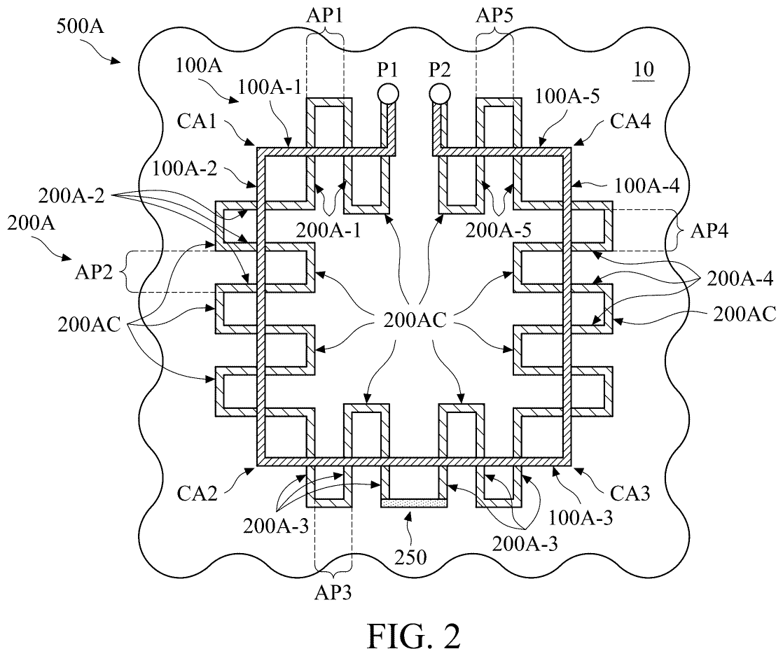

FIG. 1 is a schematic plan view of a semiconductor device 500A in accordance with some embodiments of the disclosure, showing the arrangements of the semiconductor device 500A when a switch circuit 250 is in off-state. FIG. 2 is a schematic plan view of the semiconductor device 500A in accordance with some embodiments of the disclosure, showing the arrangements of the semiconductor device 500A when the switch circuit 250 is in on-state.

In some embodiments, the semiconductor device 500A is a tunable inductor component arranged in/on a semiconductor chip (or a substrate) 10 of a semiconductor package (not shown). For example, the semiconductor device 500A can be integrated in an interconnection structure (not shown) of the semiconductor chip (or substrate) 10. In addition, the semiconductor device 500A has a first port P1 and a second port P2. As shown in FIGS. 1 and 2, the semiconductor device 500A includes a first inductor 100A, a second inductor 200A and a switch circuit 250.

The first inductor 100A is coupled between the first port P1 and the second port P2 of the semiconductor device 500A. In some embodiments, the first inductor 100A is a single-turn inductor formed by one square loop coil. As shown in FIGS. 1 and 2, the first inductor 100A includes a first strip part 100A-1, a second strip part 100A-2, a third strip part 100A-3 and a fourth strip part 100A-4. The first strip part 100A-1 is disposed close and coupled to the first port P1. The second strip part 100A-2 is connected to the first strip part 100A-1. The third strip part 100A-3 connected to the second strip part 100A-2. The fourth strip part 100A-4 is connected to the third strip part 100A-3 and coupled to the second port P2.

The first inductor 100A may be formed in a metal layer (e.g., the top metal layer) of the interconnection structure (not shown) of the semiconductor chip (or substrate) 10. In some embodiments, the first inductor 100A may be formed by single loop coil having various top view shape. For example, the top view shape of the first inductor 100A may include circular, oval, or other polygonal shapes and not limited to the disclosed embodiments.

The second inductor 200A and the switch circuit 250 are connected in series. In some embodiments, the series connected second inductor 200A and the switch circuit 250 are coupled between the first port P1 and the second port P2.

In addition, the series connected second inductor 200A and the switch circuit 250 overlap the first inductor 100A. For example, the second inductor 200A and the switch circuit 250 may overlap the first inductor 100A in the direction of a vertical projection to the semiconductor chip (or substrate) 10. In the top view shown in FIG. 1 (or FIG. 2), the second inductor 200A and the switch circuit 250 are disposed directly below the first inductor 100A. In some embodiments, the second inductor 200A may be formed in a metal layer of the interconnection structure (not shown) of the semiconductor chip (or substrate) 10 located under the metal layer where the first inductor 100A is formed in. The switch circuit 250 (e.g., a metal-oxide-semiconductor field-effect transistor (MOSFET)) may be formed on the semiconductor chip (or substrate) 10 and coupled to the second inductor 200A using metal layers of the semiconductor chip (or substrate) 10 located under the metal layer where the second inductor 200A is formed in and vias.

In some embodiments, the second inductor 200A includes at least one group of vertical portions, and each group of vertical portions includes at least one vertical portion. In some embodiments, the second inductor 200A may include at least one vertical portion. In some embodiments, the second inductor 200A may include several groups of vertical portions. For example, the second inductor 200A includes a plurality of first vertical portions 200A-1, a plurality of second vertical portions 200A-2, a plurality of third vertical portions 200A-3, a plurality of fourth vertical portions 200A-4, and a plurality of fifth vertical portions 200A-5.

The first vertical portions 200A-1 may be parallel to each other and arranged substantially along the extending direction of the first strip part 100A-1 by a pitch AP1. The first vertical portions 200A-1 are disposed directly below the corresponding first strip part 100A-1. In some embodiments, the first vertical portions 200A-1 are perpendicular to the corresponding first strip part 100A-1 in the top view shown in FIG. 1 or FIG. 2. In some embodiments, in the top view shown in FIG. 1 or FIG. 2, at least one first vertical portion 200A-1 intersects and/or overlaps the corresponding first strip portion 100A-1 in a vertical manner but does not contact it. In some embodiments, the at least one first vertical portion 200A-1 intersects and/or overlaps the corresponding first strip portion 100A-1 at an acute or obtuse angle but does not contact it. As a result, a plurality of first vertical portions 200A-1 may not be parallel to each other. For example, two first vertical portions 200A-1 are arranged at an acute angle. Therefore, it should be understood that the second inductor 200A includes at least one portion that intersects with the first strip portion 100A-1, and both the number of intersecting portions and the angles of intersection can be freely adjusted as needed. In some embodiments, when the at least one portion of the second inductor 200A intersects perpendicularly with the first strip portion 100A-1, the second inductor 200A provides enhanced shielding benefits when the switch circuit 250 is turned off.

The second vertical portions 200A-2 may be parallel to each other and arranged substantially along the extending direction of the second strip part 100A-2 by a pitch AP2. The second vertical portions 200A-2 are disposed directly below the corresponding second strip part 100A-2. In some embodiments, the second vertical portions 200A-2 are perpendicular to the corresponding second strip part 100A-2 in the top view shown in FIG. 1 or FIG. 2. In some embodiments, in the top view shown in FIG. 1 or FIG. 2, at least one second vertical portion 200A-2 intersects and/or overlaps the corresponding second strip portion 100A-2 in a vertical manner but do not contact it. In some embodiments, at least one second vertical portion 200A-2 intersects and/or overlaps the corresponding second strip portion 100A-2 at an acute or obtuse angle but does not contact it.

In some embodiments, the two adjacent first and second vertical portions 200A-1 and 200A-2 are directly connected to each other. For example, in the top view shown in FIG. 1, the first vertical portion 200A-1 and the second vertical portion 200A-2 closest to a first corner CA1 formed by the first strip part 100A-1 and the second strip part 100A-2 are directly connected to each other.

The third vertical portions 200A-3 may be parallel to each other and arranged substantially along the extending direction of the third strip part 100A-3 by a pitch AP3. The third vertical portions 200A-3 are disposed directly below the corresponding third strip part 100A-3. In some embodiments, the third vertical portions 200A-3 are perpendicular to the corresponding third strip part 100A-3 in the top view shown in FIG. 1. In some embodiments, in the top view shown in FIG. 1 or FIG. 2, at least one third vertical portion 200A-3 intersects and/or overlaps the corresponding third strip portion 100A-3 in a vertical manner but does not contact it. In some embodiments, at least one third vertical portions 200A-3 intersects and/or overlaps the corresponding third strip portion 100A-3 at an acute or obtuse angle but does not contact it.

In some embodiments, the two adjacent second and third vertical portions 200A-2 and 200A-3 are directly connected to each other. For example, in the top view shown in FIG. 1 or FIG. 2, the second vertical portion 200A-2 and the third vertical portion 200A-2 closest to a second corner CA2 formed by the second strip part 100A-2 and the third strip part 100A-3 are directly connected to each other.

The fourth vertical portions 200A-4 are parallel to each other and arranged substantially along the extending direction of the fourth strip part 100A-4 by a pitch AP4. The fourth vertical portions 200A-4 are disposed directly below the corresponding fourth strip part 100A-4. In some embodiments, the fourth vertical portions 200A-4 are perpendicular to the corresponding fourth strip part 100A-4 in the top view shown in FIG. 1. In some embodiments, in the top view shown in FIG. 1 or FIG. 2, at least one fourth vertical portion 200A-4 intersects and/or overlaps the corresponding fourth strip portion 100A-4 in a vertical manner but does not contact it. In some embodiments, at least one fourth vertical portion 200A-4 intersects and/or overlaps the corresponding fourth strip portion 100A-4 at an acute or obtuse angle but does not contact it.

In some embodiments, the two adjacent third and fourth vertical portions 200A-3 and 200A-4 are directly connected to each other. For example, in the top view shown in FIG. 1, the third vertical portion 200A-3 and the fourth vertical portion 200A-4 closest to a third corner CA3 formed by the third strip part 100A-3 and the fourth strip part 100A-4 are directly connected to each other.

The fifth vertical portions 200A-5 are parallel to each other and arranged substantially along the extending direction of the fifth strip part 100A-5 by a pitch AP5. The fifth vertical portions 200A-5 are disposed directly below the corresponding fifth strip part 100A-5. In some embodiments, the fifth vertical portions 200A-5 are perpendicular to the corresponding fifth strip part 100A-5 in the top view shown in FIG. 1 or FIG. 2. In some embodiments, in the top view shown in FIG. 1 or FIG. 2, at least one fifth vertical portion 200A-5 intersects and/or overlaps the corresponding fifth strip portion 100A-5 in a vertical manner but does not contact it. In some embodiments, at least one fifth vertical portion 200A-5 intersects and/or overlaps the corresponding fifth strip portion 100A-5 at an acute or obtuse angle but does not contact it.

In some embodiments, the two adjacent fourth and fifth vertical portions 200A-4 and 200A-5 are directly connected to each other. For example, in the top view shown in FIG. 1 or FIG. 2, the fourth vertical portion 200A-4 and the fifth vertical portion 200A-5 closest to a fourth corner CA4 formed by the fourth strip part 100A-4 and the fifth strip part 100A-5 are directly connected to each other.

In some embodiments, the first vertical portions 200A-1, the second vertical portions 200A-2, the third vertical portions 200A-3, the fourth vertical portions 200A-4, and the fifth vertical portions 200A-5 may have the same structure and size but extend in different directions that are perpendicular to the corresponding first strip part 100A-1, second strip part 100A-2, third strip part 100A-3, fourth strip part 100A-4 and fifth strip part 100A-5.

In some embodiments, the pitches AP1, AP2, AP3, AP4 and AP5 may have the same value. Alternatively, the pitches AP1, AP2, AP3, AP4 and AP5 may have different values.

It should be noted that the number of groups of vertical portions of the second inductor 200A may correspond to the number of strip parts of the first inductor 100A and is not limited to the disclosed embodiment.

In some embodiments, the second inductor 200A further includes a plurality of connection portions 200AC. The connection portions 200AC are connected between adjacent terminals of the adjacent first vertical portions 200A-1, between adjacent terminals of the adjacent second vertical portions 200A-2, between adjacent terminals of the adjacent third vertical portions 200A-3, between adjacent terminals of the adjacent fourth vertical portions 200A-4, and between adjacent terminals of the adjacent fifth vertical portions 200A-5.

In some embodiments, the connection portions 200AC connected between the adjacent first vertical portions 200A-1 may extend substantially perpendicular to the first vertical portions 200A-1 (or substantially parallel to the first strip part 100A-1). In addition, the size of the connection portions 200AC connected between the adjacent first vertical portions 200A-1 may be the same as the pitch AP1.

In some embodiments, the connection portions 200AC connected between the adjacent second vertical portions 200A-2 may extend substantially perpendicular to the second vertical portions 200A-2 (or substantially parallel to the second strip part 100A-2). In addition, the size of the connection portions 200AC connected between the adjacent second vertical portions 200A-2 may be the same as the pitch AP2.

In some embodiments, the connection portions 200AC connected between the adjacent third vertical portions 200A-3 may extend substantially perpendicular to the third vertical portions 200A-3 (or substantially parallel to the third strip part 100A-3). In addition, the size of the connection portions 200AC connected between the adjacent third vertical portions 200A-3 may be the same as the pitch AP3.

In some embodiments, the connection portions 200AC connected between the adjacent fourth vertical portions 200A-4 may extend substantially perpendicular to the fourth vertical portions 200A-4 (or substantially parallel to the fourth strip part 100A-4). In addition, the size of the connection portions 200AC connected between the adjacent fourth vertical portions 200A-4 may be the same as the pitch AP4.

In some embodiments, the connection portions 200AC connected between the adjacent fifth vertical portions 200A-5 may extend substantially perpendicular to the fifth vertical portions 200A-5 (or substantially parallel to the fifth strip part 100A-5). In addition, the size of the connection portions 200AC connected between the adjacent fifth vertical portions 200A-5 may be the same as the pitch AP5.

In some embodiments, some of the connection portions 200AC are located inside the first inductor 100A, while others of the connection portions 200AC are located outside the first inductor 100A. More specifically, the connection portions 200AC are alternate arranged inside and outside the first inductor 100A.

For example, in the connection portions 200AC connected between the adjacent first vertical portions 200A-1, some of the connection portions 200AC are located inside the first strip part 100A-1 of the first inductor 100A, while others of the connection portions 200AC are located outside the first strip part 100A-1 of the first inductor 100A. More specifically, the connection portions 200AC connected between the adjacent first vertical portions 200A-1 are alternate arranged inside and outside the first strip part 100A-1 of the first inductor 100A.

In the connection portions 200AC connected between the adjacent second vertical portions 200A-2, some of the connection portions 200AC are located inside the second strip part 100A-2 of the first inductor 100A, while others of the connection portions 200AC are located outside the second strip part 100A-2 of the first inductor 100A. More specifically, the connection portions 200AC connected between the adjacent second vertical portions 200A-2 are alternate arranged inside and outside the second strip part 100A-2 of the first inductor 100A.

In the connection portions 200AC connected between the adjacent third vertical portions 200A-3, some of the connection portions 200AC are located inside the third strip part 100A-3 of the first inductor 100A, while others of the connection portions 200AC are located outside the third strip part 100A-3 of the first inductor 100A. More specifically, the connection portions 200AC connected between the adjacent third vertical portions 200A-3 are alternate arranged inside and outside the third strip part 100A-3 of the first inductor 100A.

In the connection portions 200AC connected between the adjacent fourth vertical portions 200A-4, some of the connection portions 200AC are located inside the fourth strip part 100A-4 of the first inductor 100A, while others of the connection portions 200AC are located outside the fourth strip part 100A-4 of the first inductor 100A. More specifically, the connection portions 200AC connected between the adjacent fourth vertical portions 200A-4 are alternate arranged inside and outside the fourth strip part 100A-4 of the first inductor 100A.

In the connection portions 200AC connected between the adjacent fifth vertical portions 200A-5, some of the connection portions 200AC are located inside the fourth strip part 100A-5 of the first inductor 100A, while others of the connection portions 200AC are located outside fourth strip part 100A-5 of the first inductor 100A. More specifically, the connection portions 200AC connected between the adjacent fifth vertical portions 200A-5 are alternate arranged inside and outside the fifth strip part 100A-5 of the first inductor 100A.

In some embodiments as show in FIGS. 1 and 2, the switch circuit 250 is couple between two terminals of different portions of the second inductor 200A, and opposite terminals of the different portions of the second inductor 200A are couple to the first port P1 and the second port P2. For example, the switch circuit 250 is couple between two adjacent terminals of the vertical portions of the left half portion and the right half portion of the second inductor 200A. The left half portion of the second inductor 200A may include the first vertical portions 200A-1, the second vertical portions 200A-2, the left half of the third vertical portions 200A-3, and the corresponding connection portions 200AC. The right half portion of the second inductor 200A may include the fourth vertical portions 200A-4, the fifth vertical portions 200A-5, the right half of the third vertical portions 200A-3, and the corresponding connection portions 200AC. Opposite terminals of the left half portion and the right half portion portions of the second inductor 200A are couple to the first port P1 and the second port P2.

It should be noted that the adjacent terminals of the vertical portions of the different portions of the second inductor 200A for coupled to the switch circuit 250 may overlap any of the first strip part 100A-1, the second strip part 100A-2, the fourth strip part 100A-4 or the fifth strip part 100A-5 and not limited to the disclosed embodiments. In other words, the switch circuit 250 can be positioned in various locations, such as adjacent to the first, second, fourth, or fifth strip parts 100A-1, 100A-2, 100A-4, 100A-5 of the first inductor 100A. Additionally, the switch circuit 250 may replace a connection portion 200AC at a different location.

As shown in FIG. 1, when the switch circuit 250 is turned off, the second inductor 200A is electrically floating. That is to say, only the first inductor 100A is coupled between the first port P1 and the second port P2. The inductance of the semiconductor device 500A is adjusted as the inductance of the first inductor 100A. The first inductor 100A may serve as a main (primary) inductor 100A.

In this operation condition, the second inductor 200A may serve as an electrically floating patterned shield structure 200A for the overlying first inductor 100A. The first, second, third, fourth and fifth vertical portions 200A-1, 200A-2, 200A-3, 200A-4 and 200A-5 of the electrically floating patterned shield structure 200A are designed to extend from inside to outside the first inductor 100A in a direction perpendicular to the first, second, third, fourth and fifth strip portions 100A-1, 100A-2, 100A-3, 100A-4 and 100A-5 in order to capture fringe electric field at the inner and outer edges of the first inductor 100A. The first, second, third, fourth and fifth vertical portions 200A-1, 200A-2, 200A-3, 200A-4 and 200A-5 of the electrically floating patterned shield structure 200A do not cover the center area of first inductor 100A. The arrangement of the second inductor 200A may allow the magnetic field to pass freely through the center area of the first inductor 100A, thereby reducing magnetic loss of the semiconductor device 500A.

When the switch circuit 250 is turned off, the electrically floating patterned shield structure 200A is partitioned into two separated portions. The separated portions of the electrically floating patterned shield structure 200A may help prevent the flow of eddy current through the electrically floating patterned shield structure 200A. The quality factor (Q factor) of the first inductor 100A can be improved.

As shown in FIG. 2, when the switch circuit 250 is turned on, the second inductor 200A is shunt with the first inductor 100A. The second inductor 200A may serve as a secondary inductor 200A. That is to say, the first inductor 100A and the second inductor 200A are connected in parallel between the first port P1 and the second port P2. The inductance of the semiconductor device 500A is adjusted as the equivalent inductance of the first inductor 100A and the second inductor 200A connected in parallel. Since the first to fifth vertical portions 200A-1, 200A-2, 200A-3, 200A-4 and 200A-5 of the second inductor 200A are perpendicular to the corresponding first to fifth strip parts 100A-1, 100A-2, 100A-3, 100A-4 and 100A-5 of the first inductor 100A (that is to say, the first inductor 100A does not completely parallel to (or overlap) the second inductor 200A), the mutual inductance of the semiconductor device 500A can be reduced in this operation condition.

The semiconductor device 500A has the following advantages. When the switch circuit (e.g., the switch circuit 250) is turned on, the main inductor (e.g., the first inductor 100A) is connected in parallel with the secondary inductor (e.g., the second inductor 200A) to provide different inductance to adapt to different oscillation frequencies. When the switch circuit is turned on, the vertical portions (e.g., the first, second, third, fourth and fifth vertical portions 200A-1, 200A-2, 200A-3, 200A-4 and 200A-5) of the secondary inductor may result in smaller mutual inductance between the main inductor and the secondary inductor (e.g., the second inductor 200A), thereby broadening the tuning range of inductance. When the switch circuit is turned off, the electrically floating secondary inductor, which has vertical portions perpendicular to the corresponding strip part (e.g., the first, second, third, fourth or fifth strip part 100A-1, 100A-2, 100A-3, 100A-4 and 100A-5) of the main inductor, can act as a patterned shield structure for the main inductor. When the switch circuit is turned off, the main inductor has a higher quality factor due to patterned floating shielding (PFS) formed of the electrically floating secondary inductor underneath.

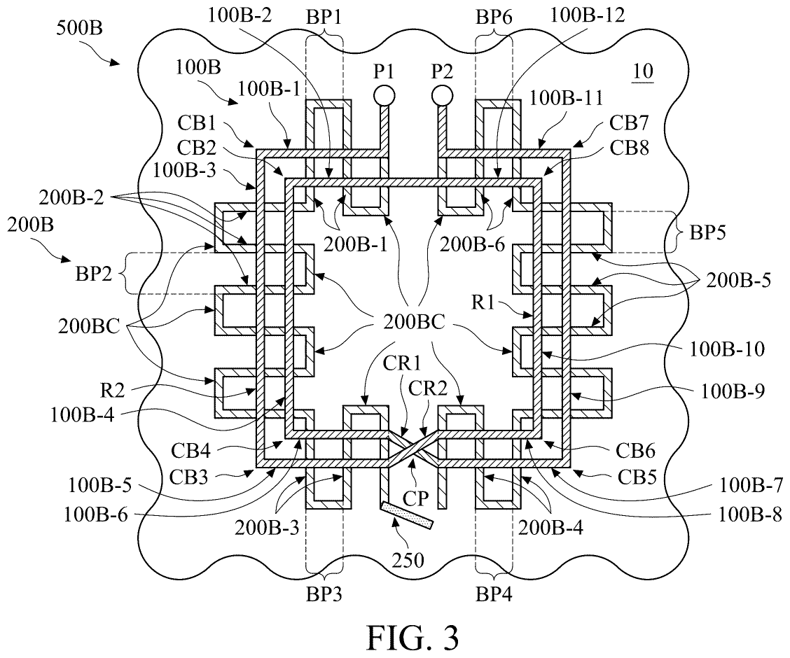

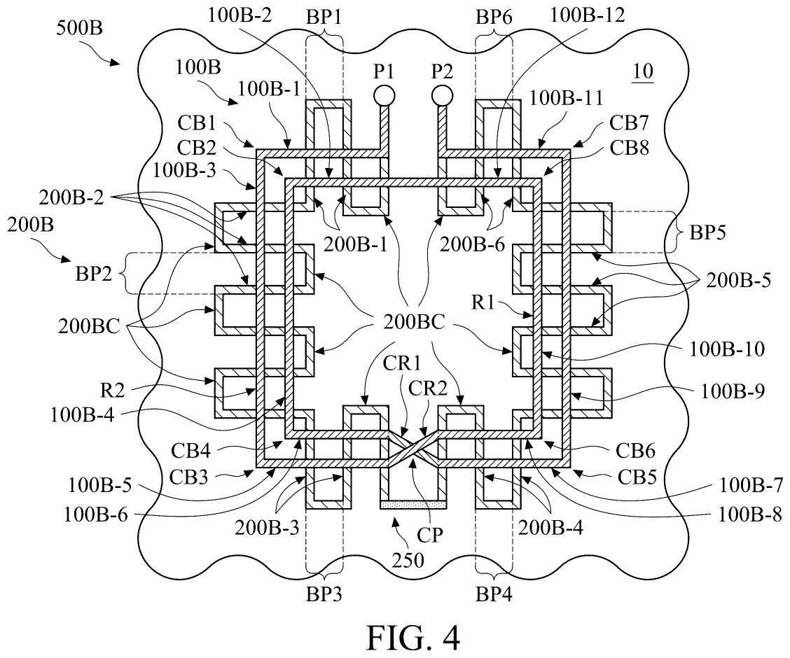

FIG. 3 is a schematic plan view of a semiconductor device 500B in accordance with some embodiments of the disclosure, showing the arrangements of the semiconductor device 500B when a switch circuit 250 is in off-state. FIG. 4 is a schematic plan view of the semiconductor device 500B in accordance with some embodiments of the disclosure, showing the arrangements of the semiconductor device 500B when the switch circuit 250 is in on-state. Elements of the embodiments hereinafter, that are the same or similar as those previously described with reference to FIGS. 1 and 2, are not repeated for brevity. As shown in FIGS. 1 to 4, the difference between the semiconductor device 500A and the semiconductor device 500B at least includes that a first inductor 100B of the semiconductor device 500B is a is a multi-turn inductor.

As shown in FIGS. 3 and 4, the semiconductor device 500B having a first port P1 and a second port P2 includes a first inductor 100B, a second inductor 200B and a switch circuit 250.

The first inductor 100B is coupled between the first port P1 and the second port P2. In some embodiments, the first inductor 100B is a multi-turn inductor formed by at least two square loop coils. As shown in FIGS. 3 and 4, the first inductor 100B, for example, a two-turn inductor, include an inner turn R1 and an outer turn R2 disposed outside the inner turn R1.

In some embodiments, the outer turn R2 of the first inductor 100B includes a first strip part 100B-1, a third strip part 100B-3, a fifth strip part 100B-5, a seventh strip part 100B-7, a ninth strip part 100B-9 and an eleventh strip part 100B-11. The first strip part 100B-1 is disposed close and coupled to the first port P1. The third strip part 100B-3 is connected to the first strip part 100B-1. The fifth strip part 100B-5 is connected to the third strip part 100B-3. The seventh strip part 100B-7 is connected to the ninth strip part 100B-9. The ninth strip part 100B-9 is connected to the eleventh strip part 100B-11. The eleventh strip part 100B-11 is disposed close and coupled to the second port P2.

In some embodiments, the inner turn R1 of the first inductor 100B includes a second strip part 100B-2, a fourth strip part 100B-4, a sixth strip part 100B-6, an eighth strip part 100B-9, a tenth strip part 100B-10 and a twelfth strip part 100B-12. The second strip part 100B-2 is disposed close to and parallel to the first strip part 100B-1. The fourth strip part 100B-4 is connected to the second strip part 100B-2. The sixth strip part 100B-6 is connected to the fourth strip part 100B-4. The eighth strip part 100B-9 is connected to the tenth strip part 100B-10. The tenth strip part 100B-10 is connected to the twelfth strip part 100B-12. The twelfth strip part 100B-12 is disposed close to the second port P2 and connected between the second strip part 100B-2 and the tenth strip part 100B-10.

The first inductor 100B further includes a first cross portion CR1 and a second cross portion CR2, so that the outer turn R2 is connected to the inner turn R1 via the first cross portion CR1 and the second cross portion CR2. For example, as shown in FIGS. 3 and 4, the first cross portion CR1 is connected between the sixth strip part 100B-6 of the inner turn R1 and the seventh strip part 100B-7 of the outer turn R2. The second cross portion CR2 is connected between the eighth strip part 100B-8 of the inner turn R1 and the fifth strip part 100B-5 of the outer turn R2.

In some embodiments, the first cross portion CR1 and the second cross portion CR2 have a crossing point CP in a top view shown in FIG. 3 or FIG. 4. In addition, the first cross portion CR1 and the second cross portion CR2 do not contact each other at the crossing point CP.

The inner turn R1 and the outer turn R2 of the first inductor 100B may be formed in the same metal layer (e.g., the top metal layer) of the interconnection structure (not shown) of the semiconductor chip (or substrate) 10. The inner turn R1 and the outer turn R2 of the first inductor 100B may have similar top view shape. In some embodiments, the inner turn R1 and the outer turn R2 of the first inductor 100B may have various top view shape. For example, the top view shape of the inner turn R1 and the outer turn R2 of the first inductor 100B may include circular, oval, or other polygonal shapes and not limited to the disclosed embodiments.

In some embodiments, one of the first cross portion CR1 and the second cross portion CR2 may be formed in different metal layers above or under the metal layer of the interconnection structure (not shown) where the inner turn R1 and the outer turn R2 are formed in. In addition, another of the first cross portion CR1 and the second cross portion CR2 may be formed in the same metal layer of the interconnection structure (not shown) where the inner turn R1 and the outer turn R2 are formed in. For example, the inner turn R1, the outer turn R2 and the second cross portion CR2 are formed in the top metal layer of the interconnection structure (not shown), and the first cross portion CR1 is formed in next-to-top metal layer of the interconnection structure (not shown).

The second inductor 200B and the switch circuit 250 are connected in series for the adjustment of the inductance of the semiconductor device 500B. In some embodiments, the series connected second inductor 200B and the switch circuit 250 are coupled between the first port P1 and the second port P2.

In addition, the series connected second inductor 200B and the switch circuit 250 overlap the first inductor 100B. For example, the second inductor 200B and the switch circuit 250 may overlap the first inductor 100B in the direction of a vertical projection to the semiconductor chip (or substrate) 10. In the top view shown in FIG. 3 (or FIG. 4), the second inductor 200B and the switch circuit 250 are disposed directly below the first inductor 100B. In some embodiments, the second inductor 200B may be formed in a metal layer under the metal layer of the interconnection structure (not shown) of the semiconductor chip (or substrate) 10 where the inner turn R1 and the outer turn R2 are formed in. The switch circuit 250 (e.g., a metal-oxide-semiconductor field-effect transistor (MOSFET)) may be formed on the semiconductor chip (or substrate) 10 and coupled to the second inductor 200A using metal layers of the semiconductor chip (or substrate) 10 located under the metal layer where the second inductor 200B is formed in and vias.

In some embodiments, the second inductor 200B includes at least one group of vertical portions, and each group of vertical portions includes at least one vertical portion. In some embodiments, the second inductor 200B may include at least one vertical portion. In some embodiments, the second inductor 200B may include several groups of vertical portions. For example, the second inductor 200B includes a plurality of first vertical portions 200B-1, a plurality of second vertical portions 200B-2, a plurality of third vertical portions 200B-3, a plurality of fourth vertical portions 200B-4, a plurality of fifth vertical portions 200B-5, and a plurality of sixth vertical portions 200B-6.

The first vertical portions 200B-1 may be parallel to each other and arranged substantially along the extending direction of the first strip part 100B-1 of the outer turn R2 and the second strip part 100B-2 of the inner turn R1 by a pitch BP1. The first vertical portions 200B-1 are disposed directly below the first strip part 100B-1 of the outer turn R2 and the second strip part 100B-2 of the inner turn R1. In some embodiments, the first vertical portions 200B-1 are perpendicular to the corresponding first strip part 100B-1 of the outer turn R2 and the second strip part 100B-2 of the inner turn R1 in the top view shown in FIG. 3 or FIG. 4. In some embodiments, in the top view shown in FIG. 3 or FIG. 4, at least one first vertical portion 200B-1 intersects and/or overlaps the corresponding first strip part 100B-1 and the second strip part 100B-2 in a vertical manner but does not contact it. In some embodiments, the at least one first vertical portion 200B-1 intersects and/or overlaps the corresponding first strip part 100B-1 and the second strip part 100B-2 at an acute or obtuse angle but does not contact it. As a result, a plurality of first vertical portions 200B-1 may not be parallel to each other. For example, two first vertical portions 200B-1 are arranged at an acute angle. Therefore, it should be understood that the second inductor 200B includes at least one portion that intersects with the first strip part 100B-1 and the second strip part 100B-2, and both the number of intersecting portions and the angles of intersection can be freely adjusted as needed. In some embodiments, when the at least one portion of the second inductor 200B intersects perpendicularly with the first strip part 100B-1 and the second strip part 100B-2, the second inductor 200B provides enhanced shielding benefits when the switch circuit 250 is turned off.

The second vertical portions 200B-2 are parallel to each other and arranged substantially along the extending direction of the third strip part 100B-3 of the outer turn R2 and the fourth strip part 100B-4 of the inner turn R1 by a pitch BP2. The second vertical portions 200B-2 are disposed directly below the third strip part 100B-3 of the outer turn R2 and the fourth strip part 100B-4 of the inner turn R1. In some embodiments, the second vertical portions 200B-2 are perpendicular to the corresponding the third strip part 100B-3 of the outer turn R2 and the fourth strip part 100B-4 of the inner turn R1 in the top view shown in FIG. 3 or FIG. 4. In some embodiments, in the top view shown in FIG. 3 or FIG. 4, at least one second vertical portion 200B-2 intersects and/or overlaps the corresponding third strip part 100B-3 and the fourth strip part 100B-4 in a vertical manner but does not contact it. In some embodiments, at least one second vertical portion 200B-2 intersects and/or overlaps the corresponding third strip part 100B-3 and the fourth strip part 100B-4 at an acute or obtuse angle but does not contact it.

In some embodiments, the two adjacent first and second vertical portions 200B-1 and 200B-2 are directly connected to each other. For example, in the top view shown in FIG. 3, the first vertical portion 200B-1 and the second vertical portion 200B-2 closest to a first corner CB1 formed by the first strip part 100B-1 and the third strip part 100B-3 and a second corner CB2 formed by the second strip part 100B-2 and the fourth strip part 100B-4 are directly connected to each other.

The third vertical portions 200B-3 may be parallel to each other and arranged substantially along the extending direction of the fifth strip part 100B-5 of the outer turn R2 and the sixth strip part 100B-6 of the inner turn R1 by a pitch BP3. The third vertical portions 200B-3 are disposed directly below the fifth strip part 100B-5 of the outer turn R2 and the sixth strip part 100B-6 of the inner turn R1. In some embodiments, the third vertical portions 200B-3 are perpendicular to the corresponding fifth strip part 100B-5 of the outer turn R2 and the sixth strip part 100B-6 of the inner turn R1 in the top view shown in FIG. 3 or FIG. 4. In some embodiments, in the top view shown in FIG. 3 or FIG. 4, at least one third vertical portion 200B-3 intersects and/or overlaps the corresponding fifth strip part 100B-5 and the sixth strip part 100B-6 in a vertical manner but does not contact it. In some embodiments, at least one third vertical portion 200B-3 intersects and/or overlaps the corresponding fifth strip part 100B-5 and the sixth strip part 100B-6 at an acute or obtuse angle but does not contact it.

In some embodiments, the two adjacent second and third vertical portions 200B-2 and 200B-3 are directly connected to each other. For example, in the top view shown in FIG. 3 or FIG. 4, the second vertical portion 200B-2 and the third vertical portion 200B-2 closest to a third corner CB3 formed by the third strip part 100B-3 and the fifth strip part 100B-5 and a fourth corner CB4 formed by the fourth strip part 100B-4 and the sixth strip part 100B-6 are directly connected to each other.

The fourth vertical portions 200B-4 may be parallel to each other and arranged substantially along the extending direction of the seventh strip part 100B-7 of the outer turn R2 and the eighth strip part 100B-8 of the inner turn R1 by a pitch BP4. The fourth vertical portions 200B-4 are disposed directly below the seventh strip part 100B-7 of the outer turn R2 and the eighth strip part 100B-8 of the inner turn R1. In some embodiments, the fourth vertical portions 200B-4 are perpendicular to the corresponding seventh strip part 100B-7 of the outer turn R2 and the eighth strip part 100B-8 of the inner turn R1 in the top view shown in FIG. 3 or FIG. 4. In some embodiments, in the top view shown in FIG. 3 or FIG. 4, at least one fourth vertical portion 200B-4 intersects and/or overlaps the corresponding the seventh strip part 100B-7 and the eighth strip part 100B-8 in a vertical manner but does not contact it. In some embodiments, at least one fourth vertical portion 200B-4 intersects and/or overlaps the corresponding the seventh strip part 100B-7 and the eighth strip part 100B-8 at an acute or obtuse angle but does not contact it.

The fifth vertical portions 200B-5 may be parallel to each other and arranged substantially along the extending direction of the ninth strip part 100B-9 of the outer turn R2 and the tenth strip part 100B-10 of the inner turn R1 by a pitch BP5. The fifth vertical portions 200B-5 are disposed directly below the ninth strip part 100B-9 of the outer turn R2 and the tenth strip part 100B-10 of the inner turn R1. In some embodiments, the fifth vertical portions 200B-5 are perpendicular to the corresponding ninth strip part 100B-9 of the outer turn R2 and the tenth strip part 100B-10 of the inner turn R1 in the top view shown in FIG. 3 or FIG. 4. In some embodiments, in the top view shown in FIG. 3 or FIG. 4, at least one fifth vertical portion 200B-5 intersects and/or overlaps the corresponding ninth strip part 100B-9 and the tenth strip part 100B-10 in a vertical manner but does not contact it. In some embodiments, at least one fifth vertical portion 200B-5 intersects and/or overlaps the corresponding ninth strip part 100B-9 and the tenth strip part 100B-10 at an acute or obtuse angle but does not contact it.

In some embodiments, the two adjacent fourth and fifth vertical portions 200B-4 and 200B-5 are directly connected to each other. For example, in the top view shown in FIG. 3 or FIG. 4, the fourth vertical portion 200B-4 and the fourth vertical portion 200B-5 closest to a fifth corner CB5 formed by the seventh strip part 100B-7 and the ninth strip part 100B-9 and a sixth corner CB6 formed by the eighth strip part 100B-8 and the tenth strip part 100B-10 are directly connected to each other.

The sixth vertical portions 200B-6 may be parallel to each other and arranged substantially along the extending direction of the eleventh strip part 100B-11 of the outer turn R2 and the twelfth strip part 100B-12 of the inner turn R1 by a pitch BP6. The sixth vertical portions 200B-6 are disposed directly below the eleventh strip part 100B-11 of the outer turn R2 and the twelfth strip part 100B-12 of the inner turn R1. In some embodiments, the sixth vertical portions 200B-6 are perpendicular to the corresponding eleventh strip part 100B-11 of the outer turn R2 and the twelfth strip part 100B-12 of the inner turn R1 in the top view shown in FIG. 3 or FIG. 4. In some embodiments, in the top view shown in FIG. 3 or FIG. 4, at least one sixth vertical portion 200B-6 intersects and/or overlaps the corresponding eleventh strip part 100B-11 and the twelfth strip part 100B-12 in a vertical manner but does not contact it. In some embodiments, at least one sixth vertical portion 200B-6 intersects and/or overlaps the corresponding eleventh strip part 100B-11 and the twelfth strip part 100B-12 at an acute or obtuse angle but does not contact it.

In some embodiments, the two adjacent fifth and sixth vertical portions 200B-5 and 200B-6 are directly connected to each other. For example, in the top view shown in FIG. 3 or FIG. 4, the fifth vertical portion 200B-5 and the sixth vertical portion 200B-6 closest to a fifth corner CB7 formed by the ninth strip part 100B-9 and the eleventh strip part 100B-11 and an eighth corner CB8 formed by the tenth strip part 100B-10 and the twelfth strip part 100B-12 are directly connected to each other.

In some embodiments, the first vertical portions 200B-1, the second vertical portions 200B-2, the third vertical portions 200B-3, the fourth vertical portions 200B-4, the fifth vertical portions 200B-5, and the sixth vertical portion 200B-6 may have the same structure and size but extend in different directions that are perpendicular to the corresponding first strip part 100B-1, third strip part 100B-3, fifth strip part 100B-5, seventh strip part 100B-7, ninth strip part 100B-9 and eleventh strip part 100B-11 of the outer turn R2, and the corresponding second strip part 100B-2, fourth strip part 100B-4, sixth strip part 100B-6, eighth strip part 100B-9, tenth strip part 100B-10 and twelfth strip part 100B-12 of the inner turn R1.

In some embodiments, the pitches BP1, BP2, BP3, BP4, BP5 and BP6 may have the same value. Alternatively, the pitches BP1, BP2, BP3, BP4, BP5 and BP6 may have the different values.

It should be noted that the number of groups of vertical portions of the second inductor 200B may correspond to the number of strip parts of the first inductor 100B and is not limited to the disclosed embodiment.

In some embodiments, the second inductor 200B further includes a plurality of connection portions 200BC. The connection portions 200BC are connected between adjacent terminals of the adjacent first vertical portions 200B-1, between adjacent terminals of the adjacent second vertical portions 200B-2, between adjacent terminals of the adjacent third vertical portions 200B-3, between adjacent terminals of the adjacent fourth vertical portions 200B-4, between adjacent terminals of the adjacent fifth vertical portions 200B-5, and between adjacent terminals of the adjacent sixth vertical portions 200B-6.

In some embodiments, the connection portions 200BC connected between the adjacent first vertical portions 200B-1 may extend substantially perpendicular to the first vertical portions 200B-1 (or substantially parallel to the first strip part 100B-1 of the outer turn R2 and the second strip part 100B-2 of the inner turn R1). In addition, the size of the connection portions 200BC connected between the adjacent first vertical portions 200B-1 may be the same as the pitch BP1.

In some embodiments, the connection portions 200BC connected between the adjacent second vertical portions 200B-2 may extend substantially perpendicular to the second vertical portions 200B-2 (or substantially parallel to the third strip part 100B-3 of the outer turn R2 and the fourth strip part 100B-4 of the inner turn R1). In addition, the size of the connection portions 200BC connected between the adjacent second vertical portions 200B-2 may be the same as the pitch BP2.

In some embodiments, the connection portions 200BC connected between the adjacent third vertical portions 200B-3 may extend substantially perpendicular to the third vertical portions 200B-3 (or substantially parallel to the fifth strip part 100B-5 of the outer turn R2 and the sixth strip part 100B-6 of the inner turn R1). In addition, the size of the connection portions 200BC connected between the adjacent third vertical portions 200B-3 may be the same as the pitch BP3.

In some embodiments, the connection portions 200BC connected between the adjacent fourth vertical portions 200B-4 may extend substantially perpendicular to the fourth vertical portions 200B-4 (or substantially parallel to the seventh strip part 100B-7 of the outer turn R2 and the eighth strip part 100B-8 of the inner turn R1). In addition, the size of the connection portions 200BC connected between the adjacent fourth vertical portions 200B-4 may be the same as the pitch BP4.

In some embodiments, the connection portions 200BC connected between the adjacent fifth vertical portions 200B-5 may extend substantially perpendicular to the fifth vertical portions 200B-5 (or substantially parallel to the ninth strip part 100B-9 of the outer turn R2 and the tenth strip part 100B-10 of the inner turn R1). In addition, the size of the connection portions 200BC connected between the adjacent fifth vertical portions 200B-5 may be the same as the pitch BP5.

In some embodiments, the connection portions 200BC connected between the adjacent sixth vertical portions 200B-6 may extend substantially perpendicular to the sixth vertical portions 200B-6 (or substantially parallel to the eleven strip part 100B-11 of the outer turn R2 and the twelfth strip part 100B-12 of the inner turn R1). In addition, the size of the connection portions 200BC connected between the adjacent sixth vertical portions 200B-6 may be the same as the pitch BP6.

In some embodiments, some of the connection portions 200BC are located inside the inner turn R1 of the first inductor 100B, while others of the connection portions 200BC are located outside the outer turn R2 of the first inductor 100B. More specifically, the connection portions 200BC are alternate arranged inside the inner turn R1 of the first inductor 100B and outside the outer turn R2 of the first inductor 100B.

For example, in the connection portions 200BC connected between the adjacent first vertical portions 200B-1, some of the connection portions 200BC are located inside the second strip part 100B-2 of the inner turn R1 of the first inductor 100B, while others of the connection portions 200BC are located outside the first strip part 100B-1 of the outer turn R2 of the first inductor 100B. More specifically, the connection portions 200BC connected between the adjacent first vertical portions 200B-1 are alternate arranged inside the second strip part 100B-2 of the inner turn R1 of the first inductor 100B and outside the first strip part 100B-1 of the outer turn R2 of the first inductor 100B.

In the connection portions 200BC connected between the adjacent second vertical portions 200B-2, some of the connection portions 200BC are located inside the fourth strip part 100B-4 of the inner turn R1 of the first inductor 100B, while others of the connection portions 200BC are located outside the third strip part 100B-3 of the outer turn R2 of the first inductor 100B. More specifically, the connection portions 200BC connected between the adjacent second vertical portions 200B-2 are alternate arranged inside the fourth strip part 100B-4 of the inner turn R1 of the first inductor 100B and outside the third strip part 100B-3 of the outer turn R2 of the first inductor 100B.

In the connection portions 200BC connected between the adjacent third vertical portions 200B-3, some of the connection portions 200BC are located inside the sixth strip part 100B-6 of the inner turn R1 of the first inductor 100B, while others of the connection portions 200BC are located outside the fifth strip part 100B-5 of the outer turn R2 of the first inductor 100B. More specifically, the connection portions 200BC connected between the adjacent third vertical portions 200B-3 are alternate arranged inside the sixth strip part 100B-6 of the inner turn R1 of the first inductor 100B and outside the fifth strip part 100B-5 of the outer turn R2 of the first inductor 100B.

In the connection portions 200BC connected between the adjacent fourth vertical portions 200B-4, some of the connection portions 200BC are located inside the eighth strip part 100B-8 of the inner turn R1 of the first inductor 100B, while others of the connection portions 200BC are located outside the seventh strip part 100B-7 of the outer turn R2 of the first inductor 100B. More specifically, the connection portions 200BC connected between the adjacent fourth vertical portions 200B-4 are alternate arranged inside the eighth strip part 100B-8 of the inner turn R1 of the first inductor 100B and outside the seventh strip part 100B-7 of the outer turn R2 of the first inductor 100B.

In the connection portions 200BC connected between the adjacent fifth vertical portions 200B-5, some of the connection portions 200BC are located inside the tenth strip part 100B-10 of the inner turn R1 of the first inductor 100B, while others of the connection portions 200BC are located outside the ninth strip part 100B-9 of the outer turn R2 of the first inductor 100B. More specifically, the connection portions 200BC connected between the adjacent fifth vertical portions 200B-5 are alternate arranged inside the tenth strip part 100B-10 of the inner turn R1 of the first inductor 100B and outside the ninth strip part 100B-9 of the outer turn R2 of the first inductor 100.

In the connection portions 200BC connected between the adjacent sixth vertical portions 200B-6, some of the connection portions 200BC are located inside the twelfth strip part 100B-12 of the inner turn R1 of the first inductor 100B, while others of the connection portions 200BC are located outside the eleventh strip part 100B-11 of the outer turn R2 of the first inductor 100B. More specifically, the connection portions 200BC connected between the adjacent sixth vertical portions 200B-6 are alternate arranged inside the twelfth strip part 100B-12 of the inner turn R1 of the first inductor 100B and outside the eleventh strip part 100B-11 of the outer turn R2 of the first inductor 100B.

In some embodiments as shown in FIGS. 3 and 4, the switch circuit 250 is couple between two terminals of different portions of the second inductor 200B, and opposite terminals of the different portions of the second inductor 200B are couple to the first port P1 and the second port P2. For example, the switch circuit 250 is couple between two adjacent terminals of the left half portion and the right half portion of the second inductor 200B. The left half portion of the second inductor 200B may include the first vertical portion 200B-1, the second vertical portion 200B-2, the third vertical portion 200B-3 and the corresponding connection portions 200BC. The right half portion of the second inductor 200B may include the fourth vertical portion 200B-4, the fifth vertical portion 200B-5, the sixth vertical portion 200B-6 and the corresponding connection portions 200BC. Opposite terminals of the left half portion and the right half portion of the second inductor 200B are couple to the first port P1 and the second port P2.

It should be noted that the adjacent terminals of the vertical portions of the different portions of the second inductor 200A for coupled to the switch circuit 250 may overlap any of the first strip part 100B-1 and the second strip part 100B-2, the third strip part 100B-3 and the fourth strip part 100B-4, the ninth strip part 100B-9 and the tenth strip part 100B-10, and the eleventh strip part 100B-11 and the twelfth strip part 100B-12 and not limited to the disclosed embodiments. In other words, the switch circuit 250 can be positioned in various locations, such as adjacent to the first, third, ninth or eleventh strip parts 100B-1, 100B-3, 100B-9, 100B-11 of the first inductor 100B. Additionally, the switch circuit 250 could replace a connection portion 200BC at a different location.

As shown in FIG. 3, when the switch circuit 250 is turned off, the second inductor 200B is electrically floating. That is to say, only the first inductor 100B is coupled between the first port P1 and the second port P2. The inductance of the semiconductor device 500A is adjusted as the inductance of the first inductor 100B. The first inductor 100B may serve as a main (primary) inductor 100B.

In this operation condition, the second inductor 200B may serve as an electrically floating patterned shield structure 200B for the overlying first inductor 100B. The first, second, third, fourth and fifth vertical portions 200B-1, 200B-2, 200B-3, 200B-4 and 200B-5 of the electrically floating patterned shield structure 200B are designed to extend from inside to outside the first inductor 100B in a direction perpendicular to the first, second, third, fourth and fifth strip portions 100B-1, 100B-2, 100B-3, 100B-4 and 100B-5 in order to capture fringe electric field at the inner and outer edges of the first inductor 100B. The first, second, third, fourth and fifth vertical portions 200B-1, 200B-2, 200B-3, 200B-4 and 200B-5 of the electrically floating patterned shield structure 200B do not cover the center area of first inductor 100B. The arrangement of the second inductor 200B may allow the magnetic field to pass freely through the center area of the first inductor 100B, thereby reducing magnetic loss of the semiconductor device 500B.

When the switch circuit 250 is turned off, the electrically floating patterned shield structure 200B is partitioned into two separated portions. The separated portions of the electrically floating patterned shield structure 200B may help prevent the flow of eddy current through the electrically floating patterned shield structure 200B. The quality factor (Q factor) of the first inductor 100B can be improved.

As shown in FIG. 4, when the switch circuit 250 is turned on, the second inductor 200B is shunt with the first inductor 100B. The second inductor 200B may serve as a secondary inductor 200B. That is to say, the first inductor 100B and the second inductor 200B are connected in parallel between the first port P1 and the second port P2. The inductance of the semiconductor device 500B is adjusted as the equivalent inductance of the first inductor 100B and the second inductor 200B connected in parallel. In this operation condition, Since the first, second, third, fourth, fifth and sixth vertical portions 200B-1, 200B-2, 200B-3, 200B-4, 200B-5 and 200B-6 of the second inductor 200B are perpendicular to the corresponding first, third, fifth, seventh, ninth and eleventh strip parts 100B-1, 100B-3, 100B-5, 100B-7, 100B-9 and 100B-11 of the outer turn R2 of the first inductor 100B, and perpendicular to the corresponding second, fourth, sixth, eighth, tenth and twelfth strip parts 100B-2, 100B-4, 100B-6, 100B-8, 100B-10 and 100B-12 of the inner turn R1 of the first inductor 100B (that is to say, the first inductor 100B does not completely parallel to (or overlap) the second inductor 200B), the mutual inductance of the semiconductor device 500B can be reduced.

The semiconductor device 500B has the following advantages. The main inductor (e.g., the first inductor 100B) includes multiple turns (e.g., the inner turn R1 and the outer turn R2) to increase the inductance, making it applicable to more scenarios. When the switch circuit (e.g., the switch circuit 250) is turned on, the main inductor is connected in parallel with the secondary inductor (e.g., the second inductor 200B) to provide different inductance to adapt to different oscillation frequencies. When the switch circuit is turned on, the vertical portions (e.g., the first, second, third, fourth, fifth and sixth vertical portions 200B-1, 200B-2, 200B-3, 200B-4, 200B-5 and 200B-6) of the secondary inductor may result in smaller mutual inductance between the main inductor and the secondary inductor, thereby broadening the tuning range of inductance. When the switch circuit is turned off, the electrically floating secondary inductor, which has vertical portions perpendicular to the corresponding strip part (e.g., the first, third, fifth, seventh, ninth and eleventh strip parts 100B-1, 100B-3, 100B-5, 100B-7, 100B-9 and 100B-11 of the outer turn R2, and the corresponding second, fourth, sixth, eighth, tenth and twelfth strip parts 100B-2, 100B-4, 100B-6, 100B-8, 100B-10 and 100B-12 of the inner turn R1) of the main inductor, can act as a patterned shield structure for the main inductor. When the switch circuit is turned off, the main inductor has a higher quality factor due to patterned floating shielding (PFS) formed of the electrically floating secondary inductor underneath.

Embodiments provided a semiconductor device. The semiconductor device includes a first port, a second port, a first inductor, a second inductor and a switch circuit. The first inductor is coupled between a first port and a second port. The first inductor includes a first strip part close to the first port. The second inductor and the switch circuit are connected in series. The series connected second inductor and the switch circuit are coupled between the first port and the second port and overlap the first inductor. The second inductor includes at least one first vertical portion that overlaps and is perpendicular to the first strip part.

In some embodiments, the first inductor and the second inductor are connected in parallel when the switch circuit is turned on.

In some embodiments, the second inductor is electrically floating when the switch circuit is turned off.

In some embodiments, the first inductor includes a second strip part connected to the first strip part, and the second inductor includes at least one second vertical portion that overlaps and is perpendicular to the second strip part.

In some embodiments, the first inductor includes a third strip part connected to the second strip part, and the second inductor includes at least one third vertical portion that overlaps and is perpendicular to the third strip part.

In some embodiments, the first inductor includes a fourth strip part connected to the third strip part, and the second inductor includes at least one fourth vertical portion that overlaps and is perpendicular to the fourth strip part.

In some embodiments, the first inductor includes a fifth strip part connected between the fourth strip part and the second port, and the second inductor includes at least one fifth vertical portion that overlaps and is perpendicular to the fifth strip part.

In some embodiments, the two adjacent first and second vertical portions are directly connected to each other, the two adjacent second and third vertical portions are directly connected to each other, the two adjacent third and fourth vertical portions are directly connected to each other, and the two adjacent fourth and fifth vertical portions are directly connected to each other.

In some embodiments, the second inductor includes a plurality of connection portions connected between the adjacent first vertical portions, the adjacent second vertical portions, the adjacent third vertical portions, the adjacent fourth vertical portions, and the adjacent fifth vertical portions.

In some embodiments, a plurality of the connection portions are located inside the first inductor, while others of the connection portions are located outside the first inductor.

Embodiments provided a semiconductor device. The semiconductor device The semiconductor device includes a first port, a second port, a first inductor, a second inductor and a switch circuit. The first inductor is coupled between the first port and the second port. The first inductor includes an inner turn and an outer turn. The inner turn includes a first strip part close to the first port. The outer turn includes a second strip part close to and parallel to the first strip part. The second inductor and a switch circuit are connected in series. The series connected second inductor and the switch circuit are coupled between the first port and the second port and overlap the first inductor. The second inductor includes at least one first vertical portion that overlaps and is perpendicular to the first strip part and the second strip part.

In some embodiments, the outer turn is connected to the inner turn via a first cross portion and a second cross portion, wherein the first cross portion and the second cross portion have a crossing point in a top view, and the first cross portion and the second cross portion do not contact each other at the crossing point.

In some embodiments, the first inductor and the second inductor are connected in parallel when the switch circuit is turned on, and the second inductor is electrically floating when the switch circuit is turned off.

In some embodiments, the outer turn of the first inductor includes a third strip part connected to the first strip part, the inner turn of the first inductor includes a fourth strip part connected to the second strip part, the fourth strip part is parallel to the third strip part, and the second inductor includes at least one second vertical portion perpendicular to the third strip part and the fourth strip part.

In some embodiments, the outer turn of the first inductor includes a fifth strip part connected between the third strip part and the second cross portion, the inner turn of the first inductor includes a sixth strip part connected between the fourth strip part and the first cross portion, the sixth strip part is parallel to the fifth strip part, and the second inductor includes at least one third vertical portion perpendicular to the fifth strip part and the sixth strip part.

In some embodiments, the outer turn of the first inductor includes a seventh strip part connected to the first cross portion, the inner turn of the first inductor includes an eighth strip part connected to the second cross portion, the eighth strip part is parallel to the seventh strip part, and the second inductor includes at least one fourth vertical portion perpendicular to the seventh strip part and the eighth strip part.

In some embodiments, the outer turn of the first inductor includes a ninth strip part connected to the seventh strip part, the inner turn of the first inductor includes a tenth strip part connected to the eighth strip part, the tenth strip part is parallel to the ninth strip part, and the second inductor includes at least one fifth vertical portion perpendicular to the ninth strip part and the tenth strip part.

In some embodiments, the outer turn of the first inductor includes an eleventh strip part connected to the ninth strip part and close to the second port, the inner turn of the first inductor includes a twelfth strip part connected between the tenth strip part and the second strip part, the twelfth strip part is parallel to the eleventh strip part, and the second inductor includes at least one sixth vertical portion perpendicular to the eleventh strip part and the twelfth strip part.

In some embodiments, the second inductor includes a plurality of connection portions respectively connecting the adjacent first strip portions, the adjacent second strip portions, the adjacent third strip portions, the adjacent fourth strip portions, the adjacent fifth strip portions, and adjacent sixth strip portions.

In some embodiments, a plurality of the connection portions are located inside the inner turn of the first inductor, while others of the connection portions are located outside the outer turn of the first inductor.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a first port and a second port;
a first inductor coupled between the first port and the second port, wherein the first inductor comprises a first strip part close to the first port; and
a second inductor and a switch circuit connected in series, wherein the series connected second inductor and the switch circuit are coupled between the first port and the second port and overlap the first inductor;
wherein the second inductor comprises at least one first vertical portion that overlaps and is perpendicular to the first strip part.

2. The semiconductor device as claimed in claim 1, wherein the first inductor and the second inductor are connected in parallel when the switch circuit is turned on.

3. The semiconductor device as claimed in claim 1, wherein the second inductor is electrically floating when the switch circuit is turned off.

4. The semiconductor device as claimed in claim 1, wherein the first inductor comprises a second strip part connected to the first strip part, and the second inductor comprises at least one second vertical portion that overlaps and is perpendicular to the second strip part.

5. The semiconductor device as claimed in claim 4, wherein the first inductor comprises a third strip part connected to the second strip part, and the second inductor comprises at least one third vertical portion that overlaps and is perpendicular to the third strip part.

6. The semiconductor device as claimed in claim 5, wherein the first inductor comprises a fourth strip part connected to the third strip part, and the second inductor comprises at least one fourth vertical portion that overlaps and is perpendicular to the fourth strip part.

7. The semiconductor device as claimed in claim 5, wherein the first inductor comprises a fifth strip part connected between the fourth strip part and the second port, and the second inductor comprises at least one fifth vertical portion that overlaps and is perpendicular to the fifth strip part.

8. The semiconductor device as claimed in claim 7, wherein the two adjacent first and second vertical portions are directly connected to each other, the two adjacent second and third vertical portions are directly connected to each other, the two adjacent third and fourth vertical portions are directly connected to each other, and the two adjacent fourth and fifth vertical portions are directly connected to each other.

9. The semiconductor device as claimed in claim 7, wherein the second inductor comprises a plurality of connection portions connected between the adjacent first vertical portions, the adjacent second vertical portions, the adjacent third vertical portions, the adjacent fourth vertical portions, and the adjacent fifth vertical portions.

10. The semiconductor device as claimed in claim 9, wherein a plurality of the connection portions are located inside the first inductor, while others of the connection portions are located outside the first inductor.

11. A semiconductor device comprising:
a first port and a second port;
a first inductor coupled between the first port and the second port, wherein the first inductor comprises an inner turn and an outer turn, and wherein the inner turn comprises a first strip part close to the first port and the outer turn comprises a second strip part close to and parallel to the first strip part; and
a second inductor and a switch circuit connected in series, wherein the series connected second inductor and the switch circuit are coupled between the first port and the second port and overlap the first inductor;
wherein the second inductor comprises at least one first vertical portions that overlaps and is perpendicular to the first strip part and the second strip part.

12. The semiconductor device as claimed in claim 11, wherein the outer turn is connected to the inner turn via a first cross portion and a second cross portion, wherein the first cross portion and the second cross portion have a crossing point in a top view, and the first cross portion and the second cross portion do not contact each other at the crossing point.

13. The semiconductor device as claimed in claim 12, wherein the first inductor and the second inductor are connected in parallel when the switch circuit is turned on, and the second inductor is electrically floating when the switch circuit is turned off.

14. The semiconductor device as claimed in claim 13, wherein the outer turn of the first inductor comprises a third strip part connected to the first strip part, the inner turn of the first inductor comprises a fourth strip part connected to the second strip part, the fourth strip part is parallel to the third strip part, and the second inductor comprises at least one second vertical portion perpendicular to the third strip part and the fourth strip part.

15. The semiconductor device as claimed in claim 14, wherein the outer turn of the first inductor comprises a fifth strip part connected between the third strip part and the second cross portion, the inner turn of the first inductor comprises a sixth strip part connected between the fourth strip part and the first cross portion, the sixth strip part is parallel to the fifth strip part, and the second inductor comprises at least one third vertical portion perpendicular to the fifth strip part and the sixth strip part.

16. The semiconductor device as claimed in claim 15, wherein the outer turn of the first inductor comprises a seventh strip part connected to the first cross portion, the inner turn of the first inductor comprises an eighth strip part connected to the second cross portion, the eighth strip part is parallel to the seventh strip part, and the second inductor comprises at least one fourth vertical portion perpendicular to the seventh strip part and the eighth strip part.

17. The semiconductor device as claimed in claim 16, wherein the outer turn of the first inductor comprises a ninth strip part connected to the seventh strip part, the inner turn of the first inductor comprises a tenth strip part connected to the eighth strip part, the tenth strip part is parallel to the ninth strip part, and the second inductor comprises at least one fifth vertical portion perpendicular to the ninth strip part and the tenth strip part.

18. The semiconductor device as claimed in claim 17, wherein the outer turn of the first inductor comprises an eleventh strip part connected to the ninth strip part and close to the second port, the inner turn of the first inductor comprises a twelfth strip part connected between the tenth strip part and the second strip part, the twelfth strip part is parallel to the eleventh strip part, and the second inductor comprises at least one sixth vertical portion perpendicular to the eleventh strip part and the twelfth strip part.

19. The semiconductor device as claimed in claim 18, wherein the second inductor comprises a plurality of connection portions respectively connecting the adjacent first strip portions, the adjacent second strip portions, the adjacent third strip portions, the adjacent fourth strip portions, the adjacent fifth strip portions, and adjacent sixth strip portions.

20. The semiconductor device as claimed in claim 19, wherein a plurality of the connection portions are located inside the inner turn of the first inductor, while others of the connection portions are located outside the outer turn of the first inductor.
